(19) United States
(12) Patent Application Publication
(10) Pub. No.: US 2014/0000364 A1
(43) Pub. Date: Jan. 2, 2014

(54) HYBRID ANALOG TO DIGITAL CONVERTER AND SENSING APPARATUS USING THE SAME

(71) Applicant: SAMSUNG ELECTRO-MECHANICS CO., LTD., Suwon (KR)

(72) Inventors: Young Kil Choi, Suwon (KR); Seung Chul Pyo, Suwon (KR); Jun Kyung Na, Suwon (KR); Sung Tae Kim, Suwon (KR); Chang Hyun Kim, Suwon (KR)

(21) Appl. No.: 13/928,328

(22) Filed: Jun. 26, 2013

(30) Foreign Application Priority Data
Jun. 29, 2012 (KR) 10-2012-0070931

(51) Int. Cl. H03M 1/12

(52) U.S. Cl. CPC H03M 1/12
USPC 73/488; 341/155; 341/172

(57) ABSTRACT

Disclosed herein are a hybrid analog to digital converter and a sensing apparatus using the same. The hybrid analog to digital converter includes: a continuous time modulator amplifying and outputting an analog differential signal; a discrete time modulator amplifying and outputting again the analog differential signal that is amplified and output by the continuous time modulator; and a comparator performing 1 bit ADC function of representing an analog signal output by the discrete time modulator to be High or Low.

### CROSS REFERENCE TO RELATED APPLICATION

This application claims the benefit of Korean Patent Application No. 10-2012-0070931, filed on Jun. 29, 2012, entitled “Hybrid Analog to Digital Converter and Sensing Apparatus Using its”, which is hereby incorporated by reference in its entirety into this application.

### BACKGROUND OF THE INVENTION

1.Technical Field

The present invention relates to a hybrid analog-to-digital converter and a sensing apparatus using the same.

2.Description of the Related Art

An inertial sensor has been widely used in various fields such as airplanes, rockets, posture control of robots, etc., and handshake correction of devices such as cameras, binoculars, etc., and navigation devices, and the application range thereof is further increased as the inertial sensor is currently included in smartphones.

Recently, as interest in the inertial sensors is increasing, interest in circuits for detecting a sensor signal and transmitting the same is also increasing.

In general, a circuit for detecting and transmitting a signal of a sensor includes a charge amplifier, a sample-and-hold unit, a low-pass filter, and an analog-to-digital converter.

The charge amplifier detects and amplifies a signal, and minimizes noise and off-sets of a circuit by using various methods.

In addition, the sample-and-hold unit performs sampling and holding to a signal detected by a sensor so that the signal may be processed by the analog-to-digital converter.

The signal processed as above passes through the low-pass filter before entering the analog-to-digital converter, and the low-pass filter performs anti-aliasing on the detected signal.

The signal that is filtered by using the low-pass filter is applied to an input of the analog-to-digital converter.

The analog-to-digital converter used in sensor applications is generally a successive approximation analog-to-digital converter (ADC) or a signal-delta (EA) ADC, and as, recently, demand on high-resolution has increased, the signal-delta ADC capable of providing high-resolution is frequently used.

A chip for an inertial sensor including the above-described circuit is mounted inside a mobile communication device. As the size of the mobile communication device such as smartphones has recently been gradually reduced, the size of the chip needs also to be reduced.

This demand on the reduced size applies not only to the sensor but also to analog and digital circuits.

To reduce the size of circuit to meet the above need, a low-dimensional process such as the 65 nm process may be used. However, this method may be a factor that increases the chip price, and as a low threshold voltage is used in this method, the increase in noise such as a leakage current may be caused.

### SUMMARY OF THE INVENTION

The present invention has been made in an effort to provide a hybrid analog-to-digital converter implemented in a hybrid method in which a filtering function and an analog-to-digital conversion function are mixed with each other to reduce a size and current consumption thereof

Further, the present invention has been made in an effort to provide a sensing apparatus using an analog-to-digital converter to reduce a size and current consumption thereof

According to a first preferred embodiment of the present invention, there is provided a hybrid analog to digital converter including: a continuous time modulator amplifying and outputting an analog differential signal; a discrete time modulator amplifying and outputting again the analog differential signal that is amplified and output by the continuous time modulator; and a comparator performing 1 bit analog-to-digital conversion (ADC) function of representing an analog signal output by the discrete time modulator to be High or Low.

The continuous time modulator may include: a first signal input circuit including a pair of variable input resistors and receiving an analog signal; and a first integration circuit including a first feedback circuit formed of a pair of variable capacitors and a first differential calculation amplifier, and amplifying and outputting a signal input by the first signal input circuit.

A gain of the second integration circuit may be adjusted by a resistance that is varied by the pair of variable input resistors and capacitance that is varied by the pair of variable capacitors.

The pair of variable input resistors may include: a first base resistor connected to a first input terminal; a second base resistor connected to a second input terminal; a first resistor unit connected between the first base resistor and a non-inverting terminal of the first integration circuit; and a second resistor unit connected between the second base resistor and an inverting terminal of the first integration circuit.

Each of the first resistor unit and the second resistor unit may include: a plurality of resistors connected in series with each other; and a plurality of switches turning on or turning off the plurality of resistors.

The pair of variable input resistors may include: a first base resistor connected between a first input terminal and a non-inverting terminal of the first integration circuit; a second base resistor connected between a second input terminal and an inverting terminal of the first integration circuit; a first resistor unit connected between the first base resistor and the non-inverting terminal of the first integration circuit; and a second resistor unit connected between the second base resistor and the inverting terminal of the first integration circuit.

Each of the first resistor unit and the second resistor unit may include: a plurality of resistors connected in parallel with each other; and a plurality of switches turning on or turning off the plurality of resistors.

The discrete time modulator may include: a second signal input circuit connected to an output terminal of the continuous time modulator and having a switched capacitor circuit structure in which it includes two types of switches opened or short-circuited by switching clocks having a phase difference of 180° from each other and a capacitor ; and a second integration circuit including a second differential calculation amplifier having an input terminal connected to the second signal input circuit and a second feedback circuit including a second feedback circuit formed of a pair of capacitors connected between input and output terminals of the second differential calculation amplifier.

The second signal input circuit may include: a first switched capacitor circuit including a first switch whose first end is connected to the first output terminal, a first capacitor whose first end is connected to a second end of the first switch, a second switch whose first end is connected to a second end of the first capacitor and second end is connected to an inverting input terminal of the second differential calculation amplifier, a third switch connected between a connection node of the first capacitor and the second switch and a ground, and a fourth switch connected between a connection node of the first switch and the first capacitor and a ground ; and a second switched capacitor circuit including a fifth switch whose first end is connected to the second output terminal, a second capacitor whose first end is connected to a second end of the fifth switch, a sixth switch whose first end is connected to a second end of the second capacitor and second end is connected to a non-inverting input terminal of the second differential calculation amplifier, a seventh switch connected between a connection node of the second capacitor and the sixth switch and a ground, and an eighth switch connected between a connection node of the fifth switch and the second capacitor and a ground, wherein the first, third, fifth, and seventh switches are short-circuited or opened by a first switching clock, and the second, fourth, sixth, and eighth switches are short-circuited or opened by a second switching clock having a phase difference of 180° from the first switching clock.

According to a second preferred embodiment of the present invention, there is provided a sensing apparatus including: a sensor unit detecting and outputting an analog signal according to vibration; a charge amplifier receiving an analog signal output by the sensor unit and amplifying and outputting the analog signal; and an analog to digital converter (ADC) converting the signal input by the charge amplifier into a digital signal and outputting the digital signal.

The analog to digital converter may include: a continuous time modulator amplifying and outputting an analog differential signal output by the charge amplifier; a discrete time modulator amplifying and outputting again the analog differential signal amplified and output by the continuous time modulator; and a comparator performing 1 bit analog to digital conversion function of representing an analog signal output by the discrete time modulator to be High or Low.

The continuous time modulator may include: a first signal input circuit including a pair of variable input resistors and receiving an analog signal; and a first integration circuit including a first feedback circuit formed of a pair of variable capacitors and a first differential calculation amplifier, and amplifying and outputting a signal input by the first signal input circuit.

The discrete time modulator may include: a second signal input circuit connected to an output terminal of the continuous time modulator and having a switched capacitor circuit structure in which it includes two types of switches opened or short-circuited by switching clocks having a phase difference of 180° from each other and a capacitor ; and a second integration circuit including a second differential calculation amplifier having an input terminal connected to the second signal input circuit and a second feedback circuit formed of a pair of capacitors connected between input and output terminals of the second differential calculation amplifier.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a structural diagram of a hybrid analog-to-digital converter according to an embodiment of the present invention;

FIG. 2 illustrates a high state of a first switching clock of a discrete time modulator of FIG. 1;

FIG. 3 illustrates a high state of a second switching clock of the discrete time modulator of FIG. 1;

FIG. 4 is a detailed view illustrating a pair of variable input resistors of FIG. 1 according to an embodiment of the present invention;

FIG. 5 is a detailed view illustrating a pair of variable input resistors of FIG. 1 according to another embodiment of the present invention; and

FIG. 6 is a structural diagram of a sensing apparatus using the analog-to-digital converter of FIG. 1.

### DESCRIPTION OF THE PREFERRED EMBODIMENTS

The objects, features, and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side”, and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

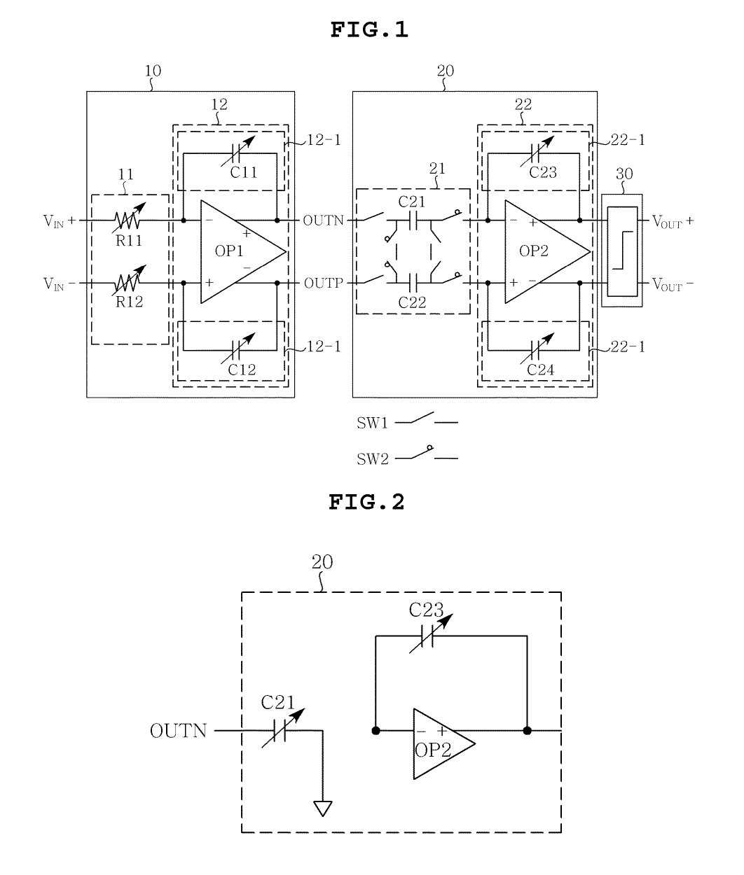

FIG. 1 is a structural diagram of a hybrid analog-to-digital converter according to an embodiment of the present invention.

Referring to FIG. 1, the hybrid analog-to-digital converter according to the current embodiment of the present invention includes a continuous time modulator 10, a discrete time modulator 20, and a comparator 30.

The continuous time modulator 10 includes a first signal input circuit 11 and a first integration circuit 12.

The first signal input circuit 11 includes a pair of variable input resistors R11 and R12 and varies a gain of the first integration circuit 12 according to a variation in resistance.

Also, the first integration circuit 12 includes a first feedback circuit 12-1 consisting of a pair of variable capacitors C11 and C12 and a first differential calculation amplifier OP1.

The continuous time modulator 10 having the above-described structure operates without sampling an input signal, and amplifies an analog signal according to an adjusted gain and transmits the same to the discrete time modulator 20.

In particular, a gain of the first integration circuit 12 is varied according to variation in resistance of the variable input resistors R11 and R12 and variation in capacitance of the variable capacitors C11 and C12, and amplifies an input analog signal according to the adjusted gain and outputs the amplified signal.

Next, the discrete time modulator 20 includes a second signal input circuit 21 and a second integration circuit 22.

The second signal input circuit 21 is connected to an output terminal of the continuous time modulator 10, and may have a switched capacitor circuit structure in which it includes two types of switches opened or short-circuited by switching clocks having a phase difference of 180° from each other, and a capacitor.

Switches that will be described below operate by two types of switching clocks consisting of a first switching clock and a second switching clock, and the first switching clock and the second switching clock have a phase difference of 180° from each other.

In FIG. 1, a switch represented as “SW1” is a switch that operates by the first switching clock, and a switch represented as “SW2” is a switch that operates by the second switching clock.

Also, in FIG. 1, reference numerals of the switches are omitted so as not to be confused in the drawings, and positions of the corresponding switches may be identified by referring to the relationships between capacitors connected to elements including the respective switches and a ground, and referring to the used switching clocks.

In detail, the second signal input circuit 21 may include a first switched capacitor circuit connected between a first output terminal OUTN and an inverting input terminal of the second differential calculation amplifier OP2 in the second integration circuit 22 and a second switched capacitor circuit connected between a second output terminal OUTP and a non-inverting input terminal of the second differential calculation amplifier OP2 in the second integration circuit 22.

The first switched capacitor circuit may include a first switch whose first end is connected to the first output terminal OUTN, a first capacitor C21 whose first end is connected to a second end of the first switch, a second switch whose first end is connected to a second end of the first capacitor C21 and whose second end is connected to the inverting input terminal of the second differential calculation amplifier OP2, a third switch that is connected between a connection node of the first capacitor C21 and the second switch and a ground, and a fourth switch that is connected between a connection node of the first switch and the first capacitor C21 and a ground.

The second switched capacitor circuit may include a fifth switch whose first end is connected to the second output terminal OUTP, a second capacitor C22 whose first end is connected to a second end of the fifth switch, a sixth switch whose first end is connected to a second end of the second capacitor C22 and whose second end is connected to the non-inverting input terminal of the second differential calculation amplifier OP2, a seventh switch connected between a connection node of the second capacitor C22 and the sixth switch and a ground, and an eighth switch connected between a connection node of the fifth switch and the second capacitor C22 and a ground.

The first, third, fifth, and seventh switches may be switches SW1 that are short-circuited or opened by the first switching clock, and the second, fourth, sixth, and eighth switches may be switches SW2 that are short-circuited or opened by the second switching clock having a phase difference of 180° from the first switching clock.

The second integration circuit 22 may include the second differential calculation amplifier OP2 having an input terminal connected to the second signal input circuit 21 and a second sub-feedback circuit 22-1 connected between input and output terminals of the second differential calculation amplifier OP2.

The second sub-feedback circuit 22-1 may include a third capacitor C23 connected between the inverting input terminal and a non-inverting output terminal of the second differential calculation amplifier OP2 and a fourth capacitor C24 connected between the non-inverting input terminal and the inverting output terminal of the second differential calculation amplifier OP2.

FIG. 2 illustrates a high state of a first switching clock of a discrete time modulator of FIG. 1.

When the first switching clock is in a high state, the second switching clock has a phase difference of 180° from the first switching clock, and then, accordingly, the discrete time modulator 20 having the above-described configuration is in a low state. Under this condition, in the discrete time modulator 20, as illustrated in FIG. 2, the switches represented as “SW1” in FIG. 1 are in a short-circuited state, and the switches represented as “SW2” are in an open state.

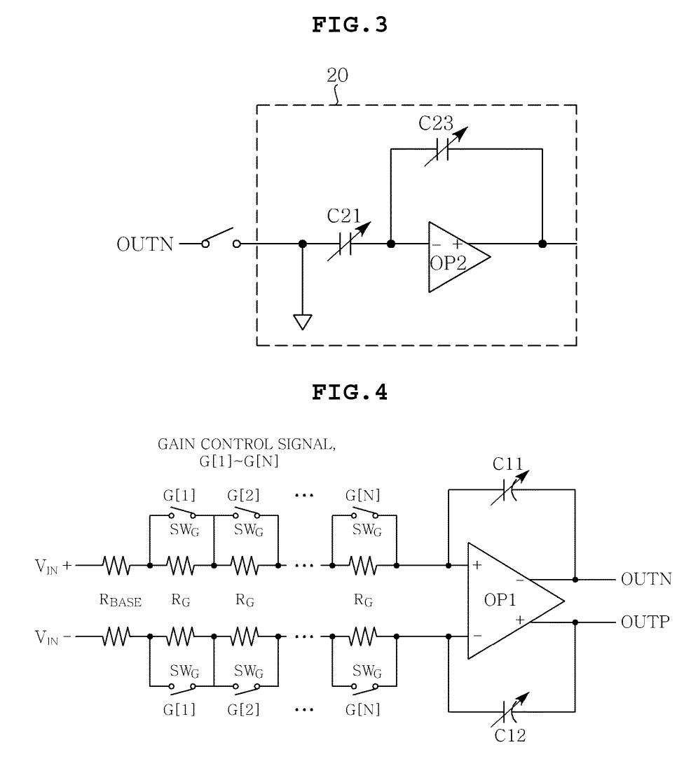

Next, FIG. 3 is a circuit diagram of the discrete time modulator 20 of FIG. 1 according to an embodiment of the present invention, in the case when the second switching clock is in a high state.

As described above with reference to FIG. 2, the first switching clock has a phase difference of 180° from the second switching clock, and thus, the first switching clock is in a low state. That is, referring to FIG. 3, the switches represented as “SW1” are in an open state, and the switches represented as “SW2” are short-circuited.

The discrete time modulator 20 having the above-described configuration amplifies and outputs a differential signal that is output by the continuous time modulator 10.

In addition, the comparator 30 performs 1 bit ADC function of representing an input analog signal to be HIGH or LOW.

A hybrid analog-to-digital converter according to the current embodiment of the present invention controls a gain of a continuous time modulator by using a variable input resistor and a variable capacitor. Therefore, the size of the hybrid analog-to-digital converter may be reduced as compared to the hybrid analog-to-digital converter according to the prior art including a separate gain control circuit, and a low-power consumption system may be established.

FIG. 4 is a detailed view illustrating a pair of variable input resistors R11 and R12 of FIG. 1 according to an embodiment of the present invention.

Referring to FIG. 4, each of the variable input resistors R11 and R12 of FIG. 1 is formed of a base resistor R_{BASE} which is connected between first and second input nodes Vin+ and Vin− and input terminals TP and TN of the first differential calculation amplifier OP1, a plurality of resistors R_{G} that are connected in serial with each other between the base resistor R_{BASE} and an input terminal of the first differential calculation amplifier OP1, and a plurality of switches SW_{G} for turning on or turning off the plurality of resistors R_{G}.

The variable input resistors R11 and R12 having the above-described structure may control gains by applying a gain control signal G[1] through G[N] to the plurality of switches SW_{G}.

When a gain is controlled by connecting the resistors in serial with each other as described above, an on-resistance of a switch SW_{G}, for example, a metal-oxide-semiconductor field effect transistor (MOSFET), has to be smaller than a resistor Rg, and thus, the size of the switch SW_{G} may preferably be increased. However, since voltages of two ends of each of the switches SW_{G} have an input signal component due to the on-resistance of the switches SW_{G} connected in serial with each other, the on-resistance of the switches SW_{G} is varied according to a variation in the voltages of the two ends of the switches SW_{G}, and a signal is likely to be distorted accordingly.

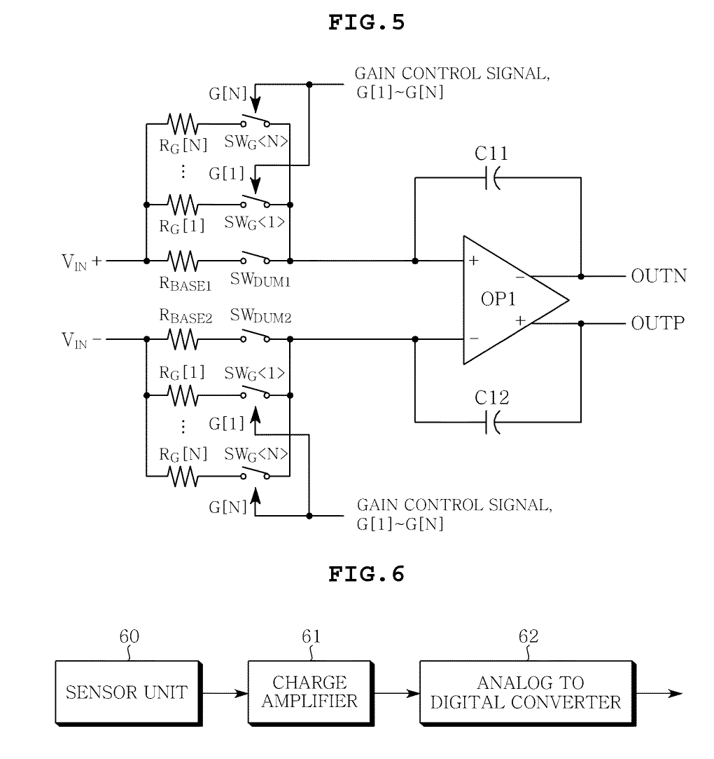

FIG. 5 is a detailed view illustrating a pair of variable input resistors R11 and R12 of FIG. 1 according to another embodiment of the present invention.

As illustrated in FIG. 5, the variable input resistors R11 and R12 according to the current embodiment of the present invention include first and second base resistors R_{BASE1} and R_{BASE2} that are connected between first and second input nodes Vᵢₙ+, and Vᵢₙ− and two input terminals of the first differential calculation amplifier OP1, first and second switches SW_{DUM1} and SW_{DUM2} turning on or turning off the first and second base resistors R_{BASE1} and R_{BASE25} a plurality of resistors R_{G}[1] through R_{G}[N] that are connected in parallel to the first base resistor R_{BASE1}, a plurality of switches SW_{G}[1] through SW_{G}[N] turning on or turning off the plurality of resistors R_{G}[1] through R_{G}[N], a plurality of resistors R_{G}[1] through R_{G}[N] that are connected in parallel to the second base resistor R_{BASE2}, and a plurality of switches SW_{G}[1] through SW_{G}[N] respectively turning on or turning off the plurality of resistors R_{G}[1] through R_{G}[N].

The variable input resistors R11 and R12 having the above-described structure may control a gain by applying a gain control signal G[1] through G[N] to the plurality of switches SW_{G}[1] through SW_{G}[N].

When controlling a gain by connecting the plurality of resistors R_{G}[1] through R_{G}[N] to the first and second base resistors R_{BASE1} and R_{BASE2} in parallel with each other, in order to obtain the smallest gain, all of the plurality of switches SW_{G}[1] through SW_{G}[N] need to be turned off. Also, the higher the resistance of the first and second base resistors R_{BASE1} and R_{BASE2}, the smaller is the gain. However, the higher the resistances of the first and second base resistors R_{BASE1} and R_{BASE2}, the greater the circuit surface area.

FIG. 6 is a structural diagram of a sensing apparatus using the analog-to-digital converter of FIG. 1.

Referring to FIG. 6, the sensing apparatus using the analog-to-digital converter of FIG. 1 includes a sensor unit 60, a charge amplifier 61, and an analog-to-digital converter 62.

Here, the sensor unit 60 may be, for example, an inertial sensor and detects and outputs a sensing signal according to vibration, wherein the output signal is an analog signal. The charge amplifier 61 is, for example, a single input amplifier that receives a signal output by the sensor unit 60 and amplifies and outputs the same.

Then, the analog-to-digital converter 62 converts the signal that is input by the charge amplifier 61, into a digital signal and outputs the same.

In particular, the analog-to-digital converter 62 according to the current embodiment of the present invention includes a continuous time modulator and a discrete time modulator. The continuous time modulator functions as a low-pass filter simultaneously with increasing an order and performs anti-aliasing with respect to signals that are input to the discrete time modulator.

In addition, the analog-to-digital converter 62 according to the current embodiment of the present invention may perform a portion of an amplifying function which is not performed by the charge amplifier 61 by varying an amount of hysteresis resistance or a capacitor.

As the analog-to-digital converter 62 includes the continuous time modulator and the discrete time modulator, functions of a sample-and-hold circuit and a low-pass filter according to the prior art may be conducted. Therefore, the size of the circuit may be reduced and power may be saved.

In addition, distortion of data during sampling may be minimized by differentiating clocks used in the charge amplifier 61 and the analog-to-digital converter 62.

According to the embodiments of the present invention, a hybrid analog-to-digital converter is implemented in a hybrid method in which a filtering function and an analog-to-digital conversion function are mixed with each other, thereby making it possible to reduce a size and current consumption thereof

Also, according to the embodiments of the present invention, a clock that is different from a clock used in a charge amplifier is used, thereby making it possible to minimize data distortion during sampling.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations, or equivalent arrangements should be considered to be within the scope of the invention, and the detailed scope of the invention will be disclosed by the accompanying claims.

What is claimed is:

1. A hybrid analog to digital converter comprising:
a continuous time modulator amplifying and outputting an analog differential signal;
a discrete time modulator amplifying and outputting again the analog differential signal that is amplified and output by the continuous time modulator; and
a comparator performing 1 bit analog-to-digital conversion (ADC) function of representing an analog signal output by the discrete time modulator to be High or Low.

2. The hybrid analog to digital converter as set forth in claim 1, wherein the continuous time modulator includes:
a first signal input circuit including a pair of variable input resistors and receiving an analog signal; and
a first integration circuit including a first feedback circuit formed of a pair of variable capacitors and a first differential calculation amplifier, and amplifying and outputting a signal input by the first signal input circuit.

3. The hybrid analog to digital converter as set forth in claim 2, wherein a gain of the second integration circuit is adjusted by a resistance that is varied by the pair of variable input resistors and capacitance that is varied by the pair of variable capacitors.

4. The hybrid analog to digital converter as set forth in claim 2, wherein the pair of variable input resistors include:
a first base resistor connected to a first input terminal;
a second base resistor connected to a second input terminal;
a first resistor unit connected between the first base resistor and a non-inverting terminal of the first integration circuit; and
a second resistor unit connected between the second base resistor and an inverting terminal of the first integration circuit.

5. The hybrid analog to digital converter as set forth in claim 4, wherein each of the first resistor unit and the second resistor unit includes:
a plurality of resistors connected in series with each other; and
a plurality of switches turning on or turning off the plurality of resistors.

6. The hybrid analog to digital converter as set forth in claim 2, wherein the pair of variable input resistors include:
a first base resistor connected between a first input terminal and a non-inverting terminal of the first integration circuit;
a second base resistor connected between a second input terminal and an inverting terminal of the first integration circuit;
a first resistor unit connected between the first base resistor and the non-inverting terminal of the first integration circuit; and
a second resistor unit connected between the second base resistor and the inverting terminal of the first integration circuit.

7. The hybrid analog to digital converter as set forth in claim 6, wherein each of the first resistor unit and the second resistor unit includes:
a plurality of resistors connected in parallel with each other; and
a plurality of switches turning on or turning off the plurality of resistors.

8. The hybrid analog to digital converter as set forth in claim 1, wherein the discrete time modulator includes:
a second signal input circuit connected to an output terminal of the continuous time modulator and having a switched capacitor circuit structure in which it includes two types of switches opened or short-circuited by switching clocks having a phase difference of 180° from each other and a capacitor; and
a second integration circuit including a second differential calculation amplifier having an input terminal connected to the second signal input circuit and a second feedback circuit including a second feedback circuit formed of a pair of capacitors connected between input and output terminals of the second differential calculation amplifier.

9. The hybrid analog to digital converter as set forth in claim 8, wherein the second signal input circuit includes:
a first switched capacitor circuit including a first switch whose first end is connected to the first output terminal, a first capacitor whose first end is connected to a second end of the first switch, a second switch whose first end is connected to a second end of the first capacitor and second end is connected to an inverting input terminal of the second differential calculation amplifier, a third switch connected between a connection node of the first capacitor and the second switch and a ground, and a fourth switch connected between a connection node of the first switch and the first capacitor and a ground; and
a second switched capacitor circuit including a fifth switch whose first end is connected to the second output terminal, a second capacitor whose first end is connected to a second end of the fifth switch, a sixth switch whose first end is connected to a second end of the second capacitor and second end is connected to a non-inverting input terminal of the second differential calculation amplifier, a seventh switch connected between a connection node of the second capacitor and the sixth switch and a ground, and an eighth switch connected between a connection node of the fifth switch and the second capacitor and a ground,
wherein the first, third, fifth, and seventh switches are short-circuited or opened by a first switching clock, and the second, fourth, sixth, and eighth switches are short-circuited or opened by a second switching clock having a phase difference of 180° from the first switching clock.

10. A sensing apparatus comprising:
a sensor unit detecting and outputting an analog signal according to vibration;
a charge amplifier receiving an analog signal output by the sensor unit and amplifying and outputting the analog signal; and
an analog to digital converter converting the signal input by the charge amplifier into a digital signal and outputting the digital signal.

11. The sensing apparatus as set forth in claim 10, wherein the analog to digital converter includes:
a continuous time modulator amplifying and outputting an analog differential signal output by the charge amplifier;
a discrete time modulator amplifying and outputting again the analog differential signal amplified and output by the continuous time modulator; and
a comparator performing 1 bit analog to digital conversion function of representing an analog signal output by the discrete time modulator to be High or Low.

12. The sensing apparatus as set forth in claim 11, wherein the continuous time modulator includes:
a first signal input circuit including a pair of variable input resistors and receiving an analog signal; and
a first integration circuit including a first feedback circuit formed of a pair of variable capacitors and a first differential calculation amplifier, and amplifying and outputting a signal input by the first signal input circuit.

13. The sensing apparatus as set forth in claim 11, wherein the discrete time modulator includes:
a second signal input circuit connected to an output terminal of the continuous time modulator and having a switched capacitor circuit structure in which it includes two types of switches opened or short-circuited by switching clocks having a phase difference of 180° from each other and a capacitor; and
a second integration circuit including a second differential calculation amplifier having an input terminal connected to the second signal input circuit and a second feedback circuit formed of a pair of capacitors connected between input and output terminals of the second differential calculation amplifier.
